(19) United States
(12) Patent Application Publication
(10) Pub. No.: US 2013/0249083 A1
(43) Pub. Date: Sep. 26, 2013

(54) PACKAGING SUBSTRATE

(71) Applicant: UNIMICRON TECHNOLOGY CORPORATION, Taoyuan (TW)

(72) Inventors: Dyi-Chung Hu, Taoyuan (TW); Ying-Chih Chan, Taoyuan (TW); Chun-Ting Lin, Taoyuan (TW)

(73) Assignee: UNIMICRON TECHNOLOGY CORPORATION, Taoyuan (TW)

(21) Appl. No.: 13/753,906

(22) Filed: Jan. 30, 2013

(30) Foreign Application Priority Data
Mar. 23, 2012 (TW) 101205295

(51) Int. Cl. H01L 23/498

(52) U.S. Cl. CPC H01L 23/49811
USPC 257/737

(57) ABSTRACT

A packaging substrate is provided, wherein a plurality of conductive posts together with a conductive bonding layer formed thereon form a plurality of external connection structures with the same height, thereby preventing tilted stack structures and poor coplanarity in a subsequent stacking process.

### BACKGROUND OF THE INVENTION

1. Field of the Invention The present invention relates to packaging substrates, and more particularly, to a packaging substrate used in a package on package (PoP) structure.

2. Description of Related Art

With the rapid development of semiconductor packaging technologies, various package types have been developed for semiconductor devices. To improve electrical performance and save space, a plurality of packages are stacked on one another so as to form a PoP structure. In such a PoP structure, a plurality of electronic elements, such as memories, CPUs, GPUs, image application processors, can be systematically integrated so as to be applied in various kinds of low-profiled and compact-sized electronic products.

Generally, solder balls are formed between packages to achieve a PoP structure. However, it is difficult to control deviation of the volume of the solder balls, thereby easily resulting in a tilted stack structure and poor coplanarity, and even causing positional deviation of solder joints between the packages. Further, when the stacking height increases, the diameter of the solder balls must be increased accordingly. Therefore, more space is needed for the solder balls, thereby leaving less available space for circuits and electronic elements and adversely affecting continuous reduction of pitches between PoP pads. Furthermore, an increase in the volume of the solder balls can easily cause a solder bridge between the solder balls. In addition, for a packaging substrate with a semiconductor chip flip-chip disposed thereon, when an underfill is applied to fill the gap between the chip and the packaging substrate, it may overflow to contaminate surfaces of bonding pads, thereby reducing the product yield.

Accordingly, metal posts in combination with a solder material are used in stack structures so as to overcome the above-described drawbacks. Referring to FIG. 1, a conventional packaging substrate 1 has a substrate body 10 having an upper surface 10a with a circuit layer 11a and a lower surface 10b with a circuit layer 11b. The circuit layer 11a has a plurality of bonding pads 111a, a plurality of first conductive pads 110a and a plurality of second conductive pads 110b, and the circuit layer 11b has a plurality of bonding pads 111b. The bonding pads 111a, 111b are used for bonding with semiconductor chips or solder balls. The first and second conductive pads 110a, 110b are used for package stacking. An insulating protective layer 12a is formed on the upper surface 10a and the circuit layer 11a, and an insulating protective layer 12b is formed on the lower surface 10b and the circuit layer 11b. The insulating protective layers 12a, 12b have a plurality of openings for exposing the bonding pads 111a, 111b. The insulating protective layer 12a further has a plurality of openings 120a, 120b for exposing the first and second conductive pads 110a, 110b, respectively.

Further, a plurality of first metal posts 13a are formed on the first conductive pads 110a, and a plurality of second metal posts 13b are formed on the second conductive pads 110b.

The first and second metal posts 13a, 13b in combination with a solder material are used for stacking another packaging substrate on the packaging substrate 1 so as to form a package stack structure. Since the first and second metal posts 13a, 13a are not likely to deform during a reflow process, the above-described drawbacks can be overcome.

However, since the metal posts are formed by electroplating, it is not easy to control the uniformity of the height of the metal posts. Referring to FIG. 1, the height h of the second metal posts 13b is greater than the height t of the first metal posts 13a, thus easily resulting in a tilted stack structure, poor coplanarity and consequently reducing the product reliability.

Therefore, there is a need to develop a packaging substrate to overcome the above-described drawbacks.

### SUMMARY OF THE INVENTION

In view of the above-described drawbacks, the present invention provides a packaging substrate, which comprises: a substrate body having two opposite surfaces respectively provided with a circuit layer, wherein the circuit layer on at least one of the surfaces of the substrate body has a plurality of first conductive pads and a plurality of second conductive pads; an insulating protective layer formed on the substrate body and the circuit layer and having a plurality of openings for exposing the first and second conductive pads; a plurality of first conductive posts respectively formed on the first conductive pads in the openings; a plurality of second conductive posts respectively formed on the second conductive pads in the openings and having a height greater than that of the first conductive posts; a first conductive bonding layer formed on each of the first conductive posts so as for the first conductive posts and the first conductive bonding layer to form first external connection structures; and a second conductive bonding layer formed on each of the second conductive posts so as for the second conductive posts and the second conductive bonding layer to form second external connection structures, wherein the first external connection structures have a height equal to that of the second external connection structures.

In an embodiment, the circuit layer further has a plurality of bonding pads. In an embodiment, the first and second conductive posts are metal posts, such as copper posts. In an embodiment, the first and second conductive bonding layers are made of a conductive paste, such as a copper paste.

In an embodiment, the packaging substrate further comprises a surface finish layer formed on each of the first and second external connection structures. Preferably, the surface finish layer has a thickness greater than 3 um. The surface finish layer can be made of an electroplated nickel/gold, ENIG (Electroless Nickel Immersion Gold) or ENEPIG (Electroless Nickel Electroless Palladium Immersion Gold). The surface finish layer can comprise an inner electroless plated copper layer and an outer electroplated copper layer.

According to the present invention, the conductive posts together with the conductive bonding layer formed thereon form a plurality of external connection structures with the same height so as prevent tilted stack structures and poor coplanarity in a subsequent stacking process, and thus to improve the product reliability.

### BRIEF DESCRIPTION OF DRAWINGS

FIG. 1 is a schematic cross-sectional view showing a conventional packaging package;

FIGS. 2A to 2F are schematic cross-sectional views showing a method of fabricating a packaging substrate according to the present invention, wherein FIG. 2E′ shows another embodiment of FIG. 2E, and FIG. 2F′ shows another embodiment of FIG. 2F; and

FIG. 3 is a schematic cross-sectional view showing an application of the packaging substrate according to the present invention.

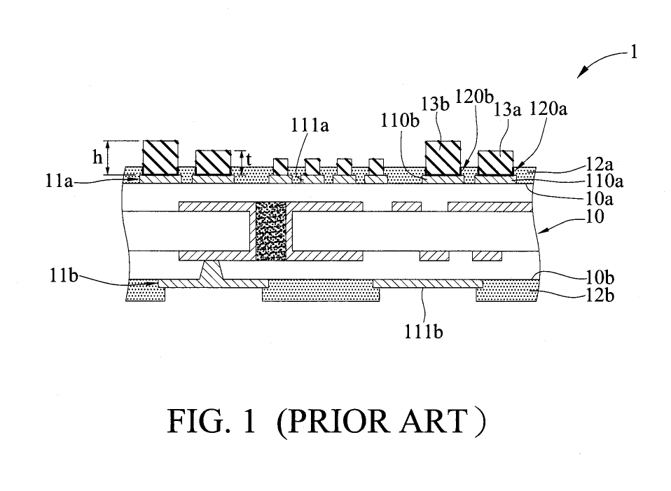

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that the drawings are only for illustrative purposes and not intended to limit the present invention. Meanwhile, terms, such as “upper”, “lower”, “a” etc., are only used as a matter of descriptive convenience and not intended to have any other significance or provide limitations for the present invention.

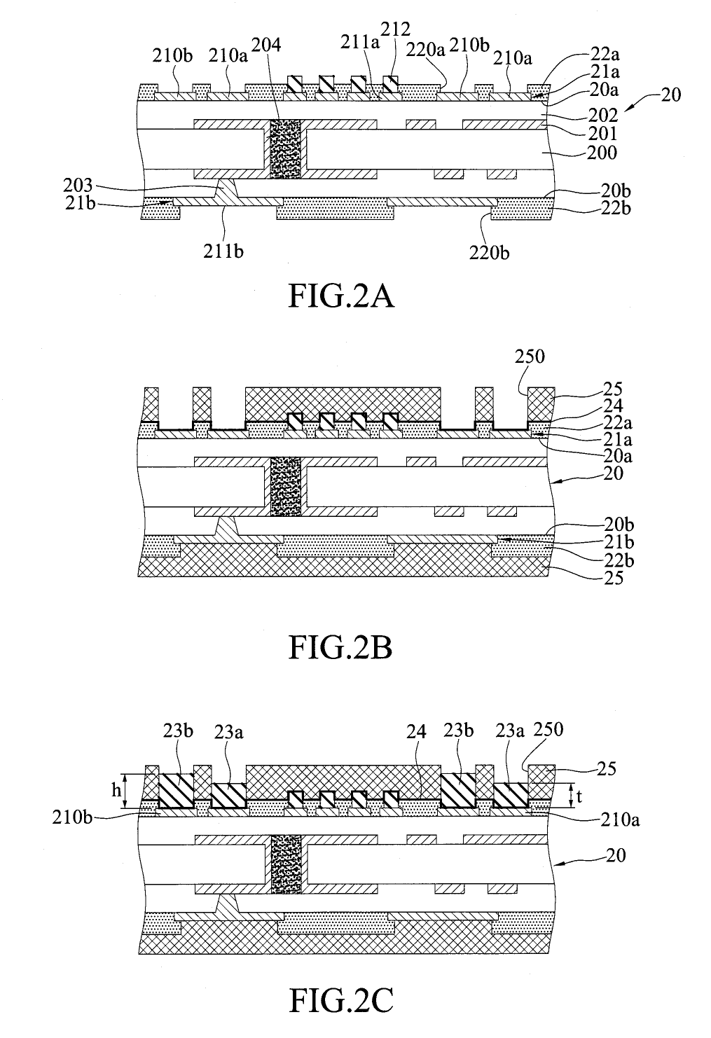

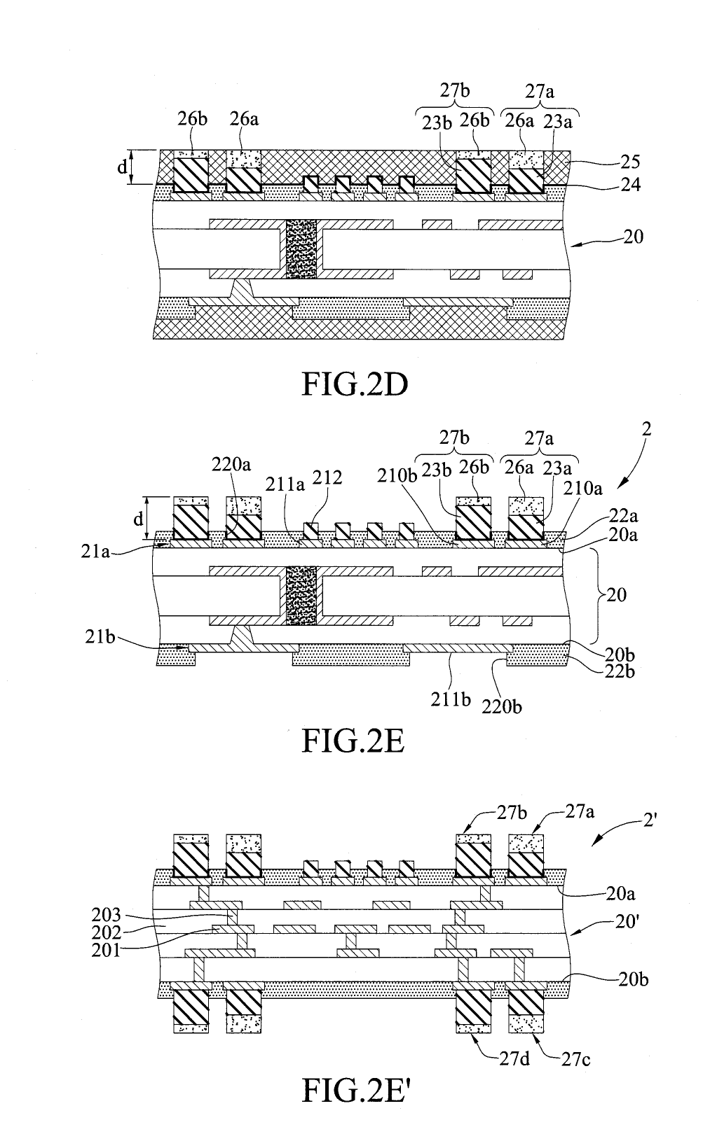

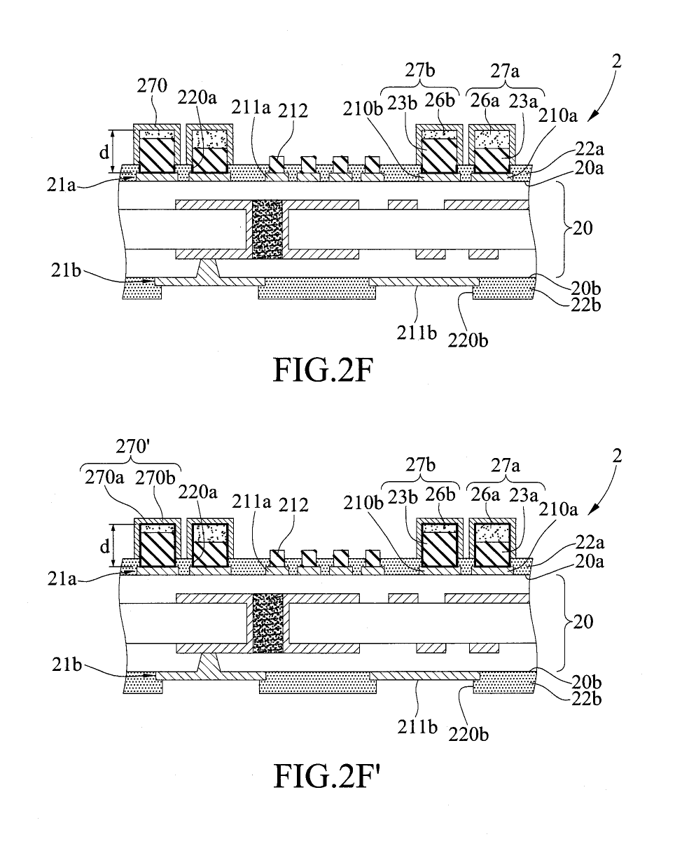

FIGS. 2A to 2E are schematic cross-sectional views showing a method of fabricating a packaging substrate 2 according to the present invention.

Referring to FIG. 2A, a substrate body 20 having an upper surface 20a and a lower surface 20b is provided. A circuit layer 21a is formed on the upper surface 20a and has a plurality of bonding pads 211a, a plurality of first conductive pads 210a and a plurality of second conductive pads 210b. A circuit layer 21b is formed on the lower surface 20b and has a plurality of bonding pads 211b.

An insulating protective layer 22a is formed on the upper surface 20a, and the circuit layer 21a and has a plurality of openings 220a for exposing the bonding pads 211a and the first and second conductive pads 210a, 210b. An insulating protective layer 22b is formed on the lower surface 20b and the circuit layer 21b and has a plurality of openings 220b for exposing the bonding pads 211b.

In an embodiment, the substrate body 20 further has a core layer 200, a plurality of internal circuits 201 formed on opposite surfaces of the core layer 200, a dielectric layer 202 formed on the core layer 200 and the internal circuits 201, a plurality of conductive vias 203 formed in the dielectric layer 202 for electrically connecting the circuit layers 21a, 21b and the internal circuits 201, and a plurality of conductive through holes 204 penetrating the core layer 200 for electrically connecting the internal circuits 201 on the opposite surfaces of the core layer 200. As such, the circuit layers 21a, 21b are the outermost circuit layer of the substrate body 20.

In an embodiment, the substrate body 20′ has a coreless internal structure. Referring to FIG. 2E′, the substrate body 20′ has a plurality of dielectric layers 202, a plurality of internal circuits 201 formed on the dielectric layers 202, and a plurality of conductive vias 203 formed in the dielectric layers 202 for electrically connecting the circuit layers 21a, 21b and the internal circuits 201. It should be noted that the substrate body can have various types of internal structures without any special limitation.

In an embodiment, the bonding pads 211a on the upper surface 20a serve as flip-chip bonding pads for electrically connecting a semiconductor chip, and hence a plurality of conductive bumps 212 are formed on the bonding pads 211a, respectively. On the other hand, the bonding pads 211b on the lower surface 20b serve as ball mounting pads. In another embodiment, the bonding pads 211a on the upper surface 20a can serve as wire bonding pads (not shown) for electrically connecting a semiconductor chip through bonding wires.

Referring to FIG. 2B, a conductive layer 24 is formed on the insulating protective layer 22a, the circuit layer 21a and the conductive bumps 212, and a resist layer 25 is further formed on the conductive layer 24, the insulating protective layer 22b and the circuit layer 21b.

Then, a patterning process is performed such that a plurality of open areas 250 are formed in the resist layer 25 for exposing the first and second conductive pads 210a, 210b.

In an embodiment, the conductive layer 24 serves as a current conductive path for a subsequent electroplating process. Furthermore, various patterning methods such as etching, exposure and development are well known in the art and detailed description thereof is omitted herein.

Referring to FIG. 2C, by using the conductive layer 24 as a current conductive path, an electroplating process is performed such that a plurality of first conductive posts 23a are respectively formed on the first conductive pads 210a and a plurality of second conductive posts 23b are respectively formed on the second conductive pads 210b. The height h of the second conductive posts 23b is greater than the height t of the first conductive posts 23a.

In an embodiment, the first and second conductive posts 23a, 23b are metal posts such as copper posts.

Referring to FIG. 2D, a first conductive bonding layer 26a is formed on each of the first conductive posts 23a by printing or coating such that the first conductive posts 23a and the first conductive bonding layer 26a form a plurality of first external connection structures 27a; and a second conductive bonding layer 26b is formed on each of the second conductive posts 23b by printing or coating such that the second conductive posts 23b and the second conductive bonding layer 26b form a plurality of second external connection structures 27b. The height d of the first external connection structures 27a is equal to the height d of the second external connection structures 27b.

In an embodiment, the first and second conductive bonding layers 26a, 26b are made of a conductive paste such as a copper paste.

Referring to FIG. 2E, the resist layer 25 and the conductive layer 24 under the resist layer 25 are removed. In another embodiment, referring to FIG. 2E′, a plurality of third and fourth external connection structures 27c, 27d are further formed on the lower surface 20b of a substrate body 20′. That is, external connection structures are formed on both the upper and lower surfaces 20a, 20b of the substrate body 20′.

Since a post made of a copper paste or made of electroplated copper in combination with a copper paste generally has a porous structure, water can easily accumulate in the porous structure during a subsequent wet process, thereby adversely affecting the quality of the structure. Therefore, referring to FIG. 2F, a surface finish layer 270 is formed on each of the first and second external connection structures 27a, 27b for facilitating a subsequent solder joint or electrical connection process.

In an embodiment, the surface finish layer 270 is made of electroplated nickel/gold, ENIG (Electroless Nickel Immersion Gold) or ENEPIG (Electroless Nickel Electroless Palladium Immersion Gold). In another embodiment, referring to FIG. 2F′, an electroless plated copper layer 270a is formed on the first and second external connection structures 27a, 27b and then an electroplated copper layer 270b is formed on the electroless plated copper layer 270 such that the electroless plated copper layer 270a and the electroplated copper layer 270b constitute a surface finish layer 270′.

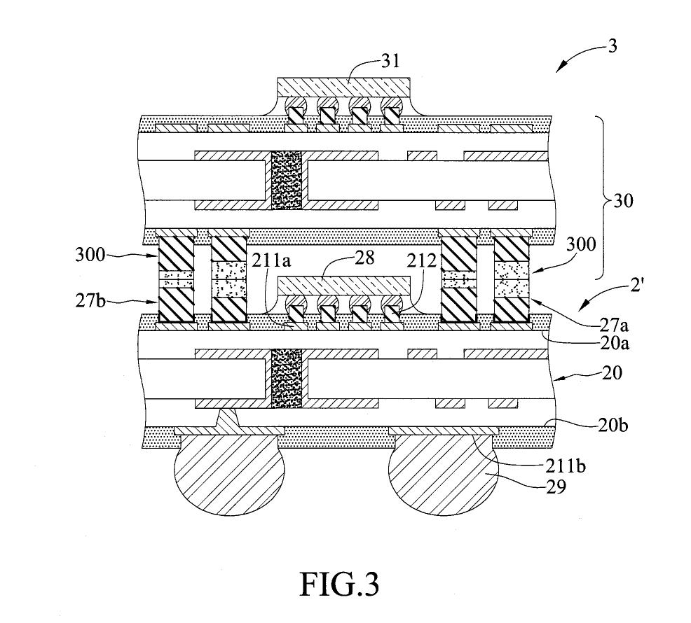

Preferably, the surface finish layer 270, 270′ has a thickness greater than 3 um. FIG. 3 is a schematic cross-sectional view showing the use of the packaging substrate 2 in subsequent packaging and stacking processes.

Referring to FIG. 3, a semiconductor chip 28 is bonded to the bonding pads 211a through the conductive bumps 212 in a flip-chip manner, and a plurality of solder balls 29 are mounted on the bonding pads 211b for electrically connecting an electronic device such as a circuit board, so as to form a semiconductor package 2′.

Then, a package 3 is bonded to the first and second external connection structures 27a, 27b. The package 3 has a packaging substrate 30, a semiconductor chip 31 disposed on the packaging substrate 30 and a plurality of external connection structures 300 formed on the packaging substrate 30. The external connection structures 30 are aligned and bonded to the first and second external connection structures 27a, 27b, respectively, so as for the package 3 to be stacked on the semiconductor package 2′, thereby forming a package stack structure. In an embodiment, the packaging substrate 30 is similar to the packaging substrate 2, and the external connection structures 30 are similar to the first and second external connection structures 27a, 27b.

In the packaging substrate 2, the first and second conductive posts 23a, 23b together with the first and second conductive bonding layers 26a, 26b respectively formed thereon constitute a plurality of first and second external connection structures 27a, 27b having the same height d, thereby preventing tilt of the packaging substrate 30 during a subsequent stacking process, improving the coplanarity and consequently effectively improving the product reliability.

The present invention further provides a packaging substrate 2, which has a substrate body 20 having an upper surface 20a with a circuit layer 21a and a lower surface 20b with a circuit layer 21b, wherein the circuit layers 21a, 21b have a plurality of bonding pads 211a, 211b, respectively, and the circuit layer 21a further has a plurality of first conductive pads 210a and a plurality of second conductive pads 210b; an insulating protective layer 22a formed on the upper surface 20a and the circuit layer 21a and an insulating protective layer 22b formed on the lower surface 20b and the circuit layer 21b, wherein the insulating protective layer 22a has a plurality of openings 220a for exposing the first and second conductive pads 210a, 210b, respectively; a plurality of first conductive posts 23a respectively formed on the first conductive pads 210a; a plurality of second conductive posts 23b respectively formed on the second conductive pads 210b and having a height greater than that of the first conductive posts 23a; a first conductive bonding layer 26a formed on each of the first conductive posts 23a so as for the first conductive posts 23a and the first conductive bonding layer 26a to form first external connection structures 27a; and a second conductive bonding layer 26b formed on each of the second conductive posts 23b so as for the second conductive posts 23b and the second conductive bonding layer 26b to form second external connection structures 27b, wherein the first external connection structures 27a have a height equal to that of the second external connection structures 27b.

In an embodiment, the first and second conductive posts 23a, 23b are metal posts, such as copper posts.

In an embodiment, the first and second conductive bonding layers 26a, 26b are made of a conductive paste such as a copper paste.

Further, a surface finish layer 270, 270′ can be formed on each of the first and second external connection structures 27a, 27b.

In an embodiment, the surface finish layer 270 is made of electroplated nickel/gold, ENIG or ENEPIG Alternatively, the surface finish layer 270′ has an inner electroless plated copper layer 270a and an outer electroplated copper layer 270b.

According to the present invention, a plurality of conductive posts together with a conductive bonding layer formed thereon constitute a plurality of external connection structures with the same height so as to facilitate a subsequent stacking process, thereby overcoming the conventional drawbacks of tilted stack structures and poor coplanarity and improving the product reliability.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A packaging substrate, comprising:
a substrate body having two opposite surfaces respectively provided with a circuit layer, wherein the circuit layer on at least one of the surfaces of the substrate body has a plurality of first conductive pads and a plurality of second conductive pads;
an insulating protective layer formed on the substrate body and the circuit layer and having a plurality of openings for exposing the first and second conductive pads;
a plurality of first conductive posts respectively formed on the first conductive pads in the openings;
a plurality of second conductive posts respectively formed on the second conductive pads in the openings and having a height greater than a height of the first conductive posts;
a first conductive bonding layer formed on each of the first conductive posts so as for the first conductive posts and the first conductive bonding layer to form first external connection structures; and
a second conductive bonding layer formed on each of the second conductive posts so as for the second conductive posts and the second conductive bonding layer to form second external connection structures, wherein the first external connection structures have a height equal to a height of the second external connection structures.

2. The packaging substrate of claim 1, wherein the circuit layer further has a plurality of bonding pads.

3. The packaging substrate of claim 1, wherein the first and second conductive posts are metal posts.

4. The packaging substrate of claim 3, wherein the metal posts are copper posts.

5. The packaging substrate of claim 1, wherein the first and second conductive bonding layers are made of a conductive paste.

6. The packaging substrate of claim 5, wherein the conductive paste is a copper paste.

7. The packaging substrate of claim 1, further comprising a surface finish layer formed on each of the first and second external connection structures.

8. The packaging substrate of claim 7, wherein the surface finish layer is made of electroplated nickel/gold, ENIG (Electroless Nickel Immersion Gold) or ENEPIG (Electroless Nickel Electroless Palladium Immersion Gold).

9. The packaging substrate of claim 7, wherein the surface finish layer comprises an inner electroless plated copper layer and an outer electroplated copper layer.

10. The packaging substrate of claim 7, wherein the surface finish layer has a thickness greater than 3 um.
